(19) United States
(12) Patent Application Publication
(10) Pub. No.: US 2026/0114046 A1
(43) Pub. Date: Apr. 23, 2026

(54) DISPLAY DEVICE AND ELECTRONIC DEVICE INCLUDING THE SAME

(71) Applicant: Samsung Display Co., LTD., Yongin-si (KR)

(72) Inventor: Keun Woo KIM, Yongin-si (KR)

(21) Appl. No.: 19/314,456

(22) Filed: Aug. 29, 2025

(30) Foreign Application Priority Data
Oct. 23, 2024 (KR) 10-2024-0145723

(51) Int. Cl. H10D 86/40; H10D 86/01; H10D 86/60

(52) U.S. Cl. CPC H10D 86/423; H10D 86/0221; H10D 86/60

(57) ABSTRACT

A display device includes a substrate, first and second transistors disposed on the substrate, and a light-emitting element electrically connected to the first transistor. The first transistor includes a first oxide semiconductor layer and a first gate electrode partially overlapping the first oxide semiconductor layer, and the second transistor includes a second oxide semiconductor layer and a second gate electrode partially overlapping the second oxide semiconductor layer. The first oxide semiconductor layer includes a first-first region, a first-second region, and a first channel region between the first-first region and the first-second region. The second oxide semiconductor layer includes a second-first region, a second-second region, and a second channel region between the second-first region and the second-second region. The first-1 and first-2 regions are doped with a first concentration, and the second-1 and second-2 regions are doped with a second concentration. The first concentration is greater than the second concentration.

This application claims priority to Korean Patent Application No. 10-2024-0145723, filed on Oct. 23, 2024, and all the benefits accruing therefrom under 35 U.S.C. § 119, the content of which in its entirety is herein incorporated by reference.

### BACKGROUND

### (a) Field

The disclosure relates to a display device.

### (b) Description of the Related Art

A display device includes pixels and may display an image on a display screen by controlling the brightness of each pixel. The display device may include a touch sensing unit capable of detecting a user's touch. The display device may include a display panel having pixels formed thereon. A touch sensing unit may be provided on the display panel. For example, the display panel may include a touch sensing unit, or a panel including a touch sensing unit may be attached to the display panel.

### SUMMARY

Embodiments are meant to provide a display device including a transistor having improved reliability.

In an embodiment of the disclosure, the display device includes a substrate, a first transistor and a second transistor disposed on the substrate, and a light-emitting element electrically connected to the first transistor wherein the first transistor includes a first oxide semiconductor layer and a first gate electrode overlapping a portion of the first oxide semiconductor layer, and the second transistor includes a second oxide semiconductor layer and a second gate electrode overlapping a portion of the second oxide semiconductor layer, wherein the first oxide semiconductor layer includes a first-first region, a first-second region, and a first channel region disposed between the first-first region and the first-second region, and wherein the second oxide semiconductor layer includes a second-first region, a second-second region, and a second channel region disposed between the second-first region and the second-second region, wherein the first-first region and the first-second region are regions doped with a first concentration, and the second-first region and the second-second region are regions doped with a second concentration, and wherein the first concentration is greater than the second concentration.

In an embodiment, the first concentration may be about 6×10¹⁴ ions per square centimeter (ions/cm²) to about 8×10¹⁴ ions/cm².

In an embodiment, the second concentration may be from about 1×10¹⁴ ions/cm² to about 3×10¹⁴ ions/cm².

In an embodiment, the first concentration may be at least twice the second concentration.

In an embodiment, the first oxide semiconductor layer and the second oxide semiconductor layer may be disposed at the same level.

In an embodiment, it may further include a third transistor including a polycrystalline semiconductor layer.

In an embodiment, the channel length of at least one of the first channel region and the second channel region may be about 3.0 micrometers or less.

In an embodiment, a gate insulating layer disposed over the first oxide semiconductor layer and the second oxide semiconductor layer may be further included.

In an embodiment, the gate insulating layer may define an opening overlapping the first-first region and the first-second region.

In an embodiment, an inter-insulating layer disposed above the gate insulating layer may be further included.

In an embodiment, the inter-insulating layer may fill at least a portion of the opening.

In an embodiment, the first gate electrode may be disposed over the first channel region, and the second gate electrode may be disposed over the second channel region.

A method for manufacturing the display device in an embodiment includes the steps of forming a first oxide semiconductor material layer and a second oxide semiconductor material layer on a substrate, forming the gate insulating layer on the first oxide semiconductor material layer and the second oxide semiconductor material layer, forming a photosensitive pattern defining a first opening on the gate insulating layer, performing a first ion implantation process on the photosensitive pattern, removing the photosensitive pattern, forming a first gate electrode and a second gate electrode on the gate insulating layer, and performing a second ion implantation process on the first gate electrode and the second gate electrode.

In an embodiment, the first oxide semiconductor material layer is formed as a first oxide semiconductor layer including a first-first region, a first-second region, and a first channel region disposed between the first-first region and the first-second region, and the second oxide semiconductor material layer is formed as a second oxide semiconductor layer including a second-first region, a second-second region, and a second channel region disposed between the second-first region and the second-second region, and the first-first region and the first-second region are regions doped with a first concentration, the second-first region and the second-second region are regions doped with a second concentration, and the first concentration may be greater than the second concentration.

In an embodiment, in the first ion implantation process, the first oxide semiconductor material layer may be at least partially doped in a region overlapping the first opening.

In an embodiment, in the second ion implantation process, the first oxide semiconductor material layer may be doped in a region that does not overlap the first gate electrode, and the second oxide semiconductor material layer may be doped in a region that does not overlap the second gate electrode.

In an embodiment, the gate insulating layer may define a second opening overlapping a portion of the first oxide semiconductor material layer.

In an embodiment, the second opening may overlap the first-first region and the first-second region.

In an embodiment, the method further comprises forming an inter-insulating layer on the first gate electrode and the second gate electrode, wherein the inter-insulating layer may fill at least a portion of the second opening.

In an embodiment, the step of forming a third transistor including a polycrystalline semiconductor layer may be further included.

By the embodiments, the reliability of the display device may be improved.

### BRIEF DESCRIPTION OF THE DRAWINGS

The above and other embodiments, advantages and features of this disclosure will become more apparent by describing in further detail embodiments thereof with reference to the accompanying drawings.

FIG. 1 is a circuit diagram of an embodiment of one pixel of a display device.

FIGS. 2 and 3 are cross-sectional views of an embodiment of a display device.

FIGS. 4 to 9 are cross-sectional views of an embodiment of a manufacturing process of a display device.

FIGS. 10 to 17 are plan views of an embodiment of one pixel.

FIG. 18 is a block diagram of an electronic device according to an embodiment.

FIG. 19 shows schematic diagrams of electronic devices according to various embodiments.

### DETAILED DESCRIPTION

Hereinafter, various embodiments of the disclosure will be described in detail with reference to the attached drawings so that a person having ordinary skill in the art to which the disclosure pertains could easily implement the disclosure. The disclosure may be embodied in many different forms and is not limited to the embodiments described herein.

In order to clearly explain the disclosure, parts irrelevant to the description are omitted, and the same reference numerals are used for identical or similar components throughout the specification.

In addition, the size and thickness of each component shown in the drawings are arbitrarily indicated for convenience of explanation, so the disclosure is not necessarily limited to that which is shown. In the drawings, the thicknesses of layers, films, panels, regions, etc., are exaggerated for clarity. And in the drawings, for convenience of explanation, the thicknesses of some layers and areas are exaggerated.

Also, when reference is made to a part, such as a layer, membrane, region, or plate, being “over” or “on” another part, this includes not only cases where it is “directly over” the other part, but also cases where there are other parts in between. In contrast, when reference is made to a part being “directly on” another part, there are no intervening parts present. Also, being “above” or “on” a reference part means being disposed above or below the reference part, and does not necessarily mean being disposed “above” or “on” it in the opposite direction of gravity.

Additionally, throughout the specification, whenever a part is said to “include” a component, this does not mean that it excludes other components, but rather that it may include other components, unless otherwise specifically stated.

Additionally, throughout the specification, when reference is made to “in a plan view,” it means when the target portion is viewed from above, and when reference is made to “in a cross-section,” it means when the target portion is viewed from the side in a cross-section cut vertically.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

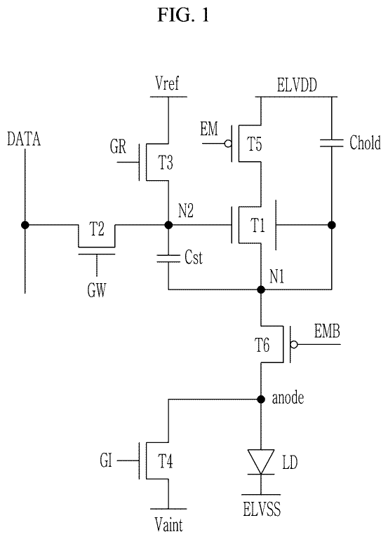

Referring to FIG. 1, a single pixel including an oxide transistor and a polycrystalline transistor is examined. FIG. 1 is a circuit diagram for one pixel. Referring to FIG. 1, one pixel may include a first transistor T1 (or driving transistor), a second transistor T2, and a first capacitor Cst (or storage capacitor). Additionally, one pixel may further include a third transistor T3, a fourth transistor T4, a fifth transistor T5, a sixth transistor T6, and a second capacitor Chold (or hold capacitor).

The first transistor T1 may be electrically connected between a first power line providing a first power voltage ELVDD and a first node N1. In an embodiment, a first electrode of the first transistor T1 may be connected to the first power line providing the first power voltage ELVDD via the fifth transistor T5, and a second electrode of the first transistor T1 may be connected to the first node N1, for example. The gate electrode of the first transistor T1 may be connected to a second node N2. The first transistor T1 further includes a lower electrode (or a second gate electrode) corresponding to the gate electrode, and the lower electrode may be connected to the first node N1. The first transistor T1 may supply driving current to a light-emitting element LD or control the amount of driving current flowing to the light-emitting element LD from the first power line that provides the first power voltage ELVDD. In an embodiment, the first transistor T1 may supply a driving current corresponding to the voltage of the first node N1 to the light-emitting element LD, for example.

The second transistor T2 may be electrically connected between a data line providing a data voltage DATA and the second node N2. The gate electrode of the second transistor T2 may be turned on in response to a first scan signal GW of the first scan line. When the second transistor T2 is turned on, the data voltage (also referred to as a data signal) DATA of the data line may be transmitted to the second node N2.

The third transistor T3 may be electrically connected between a reference power line providing a reference power voltage Vref and the second node N2. The gate electrode of the third transistor T3 is connected to the second scan line and may receive the second scan signal GR. When the third transistor T3 is turned on, the reference power voltage Vref may be transmitted to the second node N2.

The fourth transistor T4 may be electrically connected between the anode electrode of the light-emitting element LD and the second initialization power line that applies a second initialization voltage Vaint. The gate electrode of the fourth transistor T4 may be connected to a third scan line that transmits a third scan signal GI. The fourth transistor T4 may be turned on in response to the third scan signal GI. When the fourth transistor T4 is turned on, the second initialization voltage Vaint may be transmitted to the anode electrode of the light-emitting element LD.

The fifth transistor T5 may be electrically connected between the first power line that applies the first power voltage ELVDD and the first transistor T1. The gate electrode of the fifth transistor T5 may be connected to a first light-emitting control line that applies a first light-emitting control signal EM.

The sixth transistor T6 may be electrically connected between the first node N1 and the anode electrode of the light-emitting element LD. The gate electrode of the sixth transistor T6 may be connected to a second light-emitting control line that applies a second light-emitting control signal EMB.

The first capacitor Cst may be formed or electrically connected between the first node N1 and the second node N2. A voltage corresponding to the data voltage DATA may be stored in the first capacitor Cst.

The second capacitor Chold may be formed or electrically connected between the first power line applying the first power voltage ELVDD and the first node N1. The second capacitor Chold may stabilize the voltage of the first node N1.

The light-emitting element LD may be electrically connected between the sixth transistor T6 and a second power line to which a second power voltage ELVSS is applied. In an embodiment, the light-emitting element LD may be connected in the forward direction between the first node N1 and the second power line, for example. When a driving current is supplied from the first transistor T1, the light-emitting element LD may emit light with a brightness corresponding to the driving current.

In an embodiment, the light-emitting element LD may include an organic light-emitting diode. In another embodiment, the light-emitting element LD may include at least one inorganic light-emitting diode. The type, size, and/or number of light-emitting elements LD may vary depending on the embodiment.

In an embodiment, at least one of the first to sixth transistors T1 to T6 may include an oxide semiconductor. In an embodiment, the first transistor T1, the second transistor T2, the third transistor T3, and the fourth transistor T4 may be oxide semiconductor transistors including oxide semiconductors, for example. The fifth transistor T5 and the sixth transistor T6 may be polycrystalline semiconductor transistors including polycrystalline silicon.

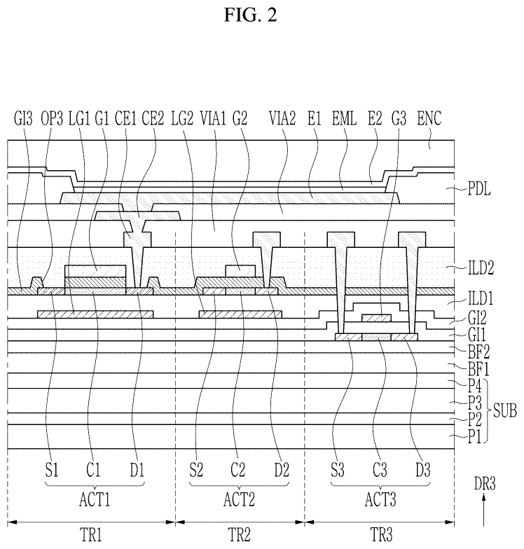

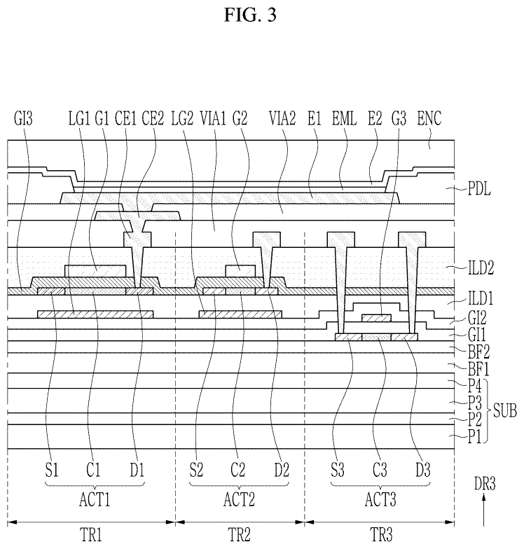

Below, with reference to FIGS. 2 and 3, a laminated structure of a display device in an embodiment will be examined. FIGS. 2 and 3 are cross-sectional views of an embodiment of the display device.

First, referring to FIG. 2, the display device in an embodiment may include a first transistor region TR1, a second transistor region TR2, and a third transistor region TR3.

A first transistor including a first gate electrode G1 and a first oxide semiconductor layer ACT1 may be disposed in the first transistor region TR1. A second transistor including a second gate electrode G2 and a second oxide semiconductor layer ACT2 may be disposed in the second transistor region TR2. A third transistor including a third gate electrode G3 and a polycrystalline semiconductor layer ACT3 may be disposed in the third transistor region TR3. Referring to FIG. 2 below, the laminated structure will be examined.

First, a substrate SUB in an embodiment may include a first plastic layer P1, a first barrier layer P2, a second plastic layer P3, and a second barrier layer P4. The substrate SUB may include a flexible material such as plastic that may be bent, folded, or rolled.

A first buffer layer BF1 and a second buffer layer BF2 may be disposed on the substrate SUB. At least one of the first buffer layer BF1 and the second buffer layer BF2 may be omitted. Each of the first buffer layer BF1 and the second buffer layer BF2 may include silicon nitride SiNx, silicon oxide SiO₂, silicon oxynitride, or the like.

The first buffer layer BF1 and the second buffer layer BF2 may block impurities from the substrate SUB during the crystallization process to form polycrystalline silicon, thereby improving the properties of the polycrystalline silicon. In addition, the first buffer layer BF1 and the second buffer layer BF2 may planarize the substrate SUB to relieve the stress on the polycrystalline semiconductor layer (hereinafter also referred to as a third semiconductor layer) ACT3 formed on the second buffer layer BF2.

A third semiconductor layer ACT3 included in the third transistor region TR3 may be disposed on the second buffer layer BF2. The third semiconductor layer ACT3 may include polycrystalline silicon.

The third semiconductor layer ACT3 may include a third-first region S3, a third-second region D3, and a third channel region C3. The third-first region S3 and the third-second region D3 are arranged on opposite sides of the third channel region C3. The third channel region C3 may include an intrinsic semiconductor that is not doped or is substantially doped with impurities, and the third-first region S3 and the third-second region D3 may include an impurity semiconductor that is doped with conductive impurities.

A first gate insulating layer GI1 may be disposed on the third semiconductor layer ACT3 and the second buffer layer BF2. The first gate insulating layer GI1 may include silicon nitride SiNx, silicon oxide SiO₂, silicon oxynitride, or the like. The first gate insulating layer GI1 may be formed on the entirety of the surface of the substrate SUB.

A first gate conductive layer may be disposed on the first gate insulating layer GI1. The first conductive layer may include a third gate electrode G3 disposed in a third transistor region TR3. The third gate electrode G3 may overlap the third channel region C3 of the third semiconductor layer ACT3.

The third gate electrode G3 may be a multi-layer laminated metal film including any one of copper (Cu), a copper alloy, aluminum (Al), an aluminum alloy, molybdenum (Mo), and a molybdenum alloy.

A second gate insulating layer GI2 may be disposed on the third gate electrode G3 and the first gate insulating layer GI1. The second gate insulating layer GI2 may include silicon nitride SiNx, silicon oxide SiO₂, or silicon oxynitride. The second gate insulating layer GI2 may be formed on the entirety of the surface of the substrate SUB.

A second gate conductive layer may be disposed on the second gate insulating layer GI2. The second gate conductive layer may include a first lower electrode LG1 disposed in the first transistor region TR1 and a second lower electrode LG2 disposed in the second transistor region TR2. The first lower electrode LG1 may overlap the first oxide semiconductor layer ACT1 to be described later. The first lower electrode LG1 may have substantially the same width as the first oxide semiconductor layer ACT1. The second lower electrode LG2 may overlap the second oxide semiconductor layer ACT2 to be described later. The second lower electrode LG2 may have substantially the same width as the second oxide semiconductor layer ACT2.

A first inter-insulating layer ILD1 may be disposed on the second gate insulating layer GI2 and the second gate conductive layer. The first inter-insulating layer ILD1 may cover the second gate conductive layer.

The oxide semiconductor layers ACT1 and ACT2 may be disposed on the first inter-insulating layer ILD1. The first oxide semiconductor layer ACT1 may be disposed in the first transistor region TR1. The second oxide semiconductor layer ACT2 may be disposed in the second transistor region TR2.

The first oxide semiconductor layer ACT1 may include a first-first region S1, a first-second region D1, and a first channel region C1. The first channel region C1 may be disposed between the first-first region S1 and the first-second region D1. The first-first region S1 and the first-second region D1 may be doped with impurities and function as electrodes.

The second oxide semiconductor layer ACT2 may include a second-first region S2, a second-second region D2, and a second channel region C2. The second channel region C2 may be disposed between the second-first region S2 and the second-second region D2. The second-first region S2 and the second-second region D2 may be doped with impurities and function as electrodes.

The first oxide semiconductor layer ACT1 and the second oxide semiconductor layer ACT2 may include an oxide semiconductor. Oxide semiconductors include single-element metal oxides such as indium oxide (In), tin oxide (Sn), or zinc oxide (Zn); binary metal oxides such as In—Zn oxides, Sn—Zn oxides, Al—Zn oxides, Zn—Mg oxides, Sn—Mg oxides, In—Mg oxides, or In—Ga oxides; In—Ga—Zn oxides, In—Al—Zn oxides, In—Sn—Zn oxides, Sn—Ga—Zn oxides, Al—Ga—Zn oxides, Sn—Al—Zn oxides, In—Hf—Zn oxides, In—La—Zn oxides, In—Ce—Zn oxides, In—Pr—Zn oxides, In—Nd—Zn oxides, In—Sm—Zn oxides, In—Eu—Zn oxides, In—Gd—Zn oxides, In—Tb—Zn oxides, In—Dy—Zn oxides, and they may include at least one of ternary metal oxides such as In—Ho—Zn oxides, In—Er—Zn oxides, In—Tm—Zn oxides, In—Yb—Zn oxides, or In—Lu—Zn oxides, and quaternary metal oxides such as In—Sn—Ga—Zn oxides, In—Hf—Ga—Zn oxides, In—Al—Ga—Zn oxides, In—Sn—Al—Zn oxides, In—Sn—Hf—Zn oxides, or In—Hf—Al—Zn oxides. In an embodiment, the semiconductor layers ACT1 and ACT2 may include indium-gallium-zinc oxide (“IGZO”) among the In—Ga—Zn-based oxides, for example.

The first-first region S1 and the first-second region D1 may be regions doped with n+ ions. In an embodiment, it could be a region doped with B+ ions, for example. The first-first region S1 and the first-second region D1 may be doped with a first concentration—for example, the first concentration may be about 6×10¹⁴ ions per square centimeter (ions/cm²) to about 8×10¹⁴ ions/cm².

The second-first region S2 and the second-second region D2 may be regions doped with n+ ions. In an embodiment, it could be a region doped with B+ ions, for example. The second-first region S2 and the second-second region D2 may be doped with a second concentration—for example, the first concentration may be about 1×10¹⁴ ions/cm² to about 3×10¹⁴ ions/cm².

The first concentration doping the first-first region S1 and the first-second region D1 may be greater than the second concentration doping the second-first region S2 and the second-second region D2. In an embodiment, the first concentration may be more than twice the second concentration, for example.

Additionally, the channel length of at least one of the first channel region C1 and the second channel region C2 may be about 3.0 micrometers or less. In an embodiment, the channel length of the first channel region C1 may be about 3.0 micrometers or less, for example. Despite the short channel length, the first oxide semiconductor layer ACT1 includes or consists of a sufficient amount of carrier, so it may be easy to secure the properties of the transistor. In addition, a high-resolution display device may be provided by reducing the size of the first transistor region TR1 including the first oxide semiconductor layer ACT1.

Both the first oxide semiconductor layer ACT1 and the second oxide semiconductor layer ACT2 may be disposed on the first inter-insulating layer ILD1. The first oxide semiconductor layer ACT1 and the second oxide semiconductor layer ACT2 may be disposed at the same level. In this case, the first oxide semiconductor layer ACT1 and the second oxide semiconductor layer ACT2 may have different doping concentrations. In particular, the doping concentration of the first oxide semiconductor layer ACT1 electrically connected to the light-emitting element may be greater than the doping concentration of the second oxide semiconductor layer ACT2. When the doping concentration of the first oxide semiconductor layer ACT1 is large, the carrier concentration may be large, and thus the reliability of the display device including the first transistor may be improved.

A third gate insulating layer GI3 may be disposed on the first oxide semiconductor layer ACT1 and the second oxide semiconductor layer ACT2. The third gate insulating layer GI3 may include silicon nitride SiNx, silicon oxide SiO₂, or silicon oxynitride. The third gate insulating layer GI3 may be formed on the entirety of the surface of the substrate SUB.

In an embodiment, the third gate insulating layer GI3 may define an opening OP3. The opening OP3 may overlap at least a portion of the first oxide semiconductor layer ACT1. The opening OP3 may overlap the first-first region S1 and the first-second region D1 of the first oxide semiconductor layer ACT1. The third gate insulating layer GI3 may expose the first-first region S1 and the first-second region D1 of the first oxide semiconductor layer ACT1.

The third gate conductive layer may be disposed on the third gate insulating layer GI3. The third conductive layer may include the first gate electrode G1 disposed in the first transistor region TR1 and the second gate electrode G2 disposed in the second transistor region TR2. The first gate electrode G1 may overlap the first channel region C1. The second gate electrode G2 may overlap the second channel region C2.

The third conductive layer may be a multilayer film in which a metal film including any one of copper (Cu), a copper alloy, aluminum (Al), an aluminum alloy, molybdenum (Mo), and a molybdenum alloy is laminated.

A second inter-insulating layer ILD2 may be disposed on the third conductive layer and the third gate insulating layer GI3. The second inter-insulating layer ILD2 may fill at least a portion of the opening OP3 of the third gate insulating layer GI3. The second inter-insulating layer ILD2 may be in direct contact with the first oxide semiconductor layer ACT1 exposed by the opening OP3.

A first data conductive layer may be disposed on a second inter-insulating layer ILD2. The first data conductive layer may include a first connection electrode CE1 electrically connected to a second connection electrode CE2 to be described later.

The first data conductive layer may include one or more metals selected from molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu). The first data conductive layer may be formed as a single layer or multiple layers.

A first via layer VIA1 may be disposed on the first data conductive layer and the second inter-insulating layer ILD2. The first via layer VIA1 may include or consist of an organic material such as polyacrylate resin, polyimide resin, or a laminated film of organic and inorganic materials.

A second data conductive layer may be disposed on the first via layer VIA1. The second data conductive layer may include the second connection electrode CE2 electrically connecting the first electrode E1 and the first connection electrode CE1.

A second via layer VIA2 may be disposed on the second data conductive layer and the first via layer VIA1. The second via layer VIA2 may include or consist of an organic material such as polyacrylate resin, polyimide resin, or a laminated film of organic and inorganic materials.

The first electrode E1 may be disposed on the second via layer VIA2. A barrier rib PDL is disposed above the first electrode E1. The barrier rib PDL defines an opening within which a light-emitting layer EML may be disposed. A second electrode E2 may be disposed on the light-emitting layer EML.

Here, the first electrode E1 may be an anode, which is a hole injection electrode, and the second electrode E2 may be a cathode, which is an electron injection electrode. However, the embodiment is not necessarily limited thereto, and depending on the driving method of the display device, the first electrode E1 may become a cathode and the second electrode E2 may become an anode.

An encapsulating layer ENC may be disposed on the second electrode E2. The encapsulating layer ENC may protect the light-emitting layer EML including or consisting of organic material from moisture or oxygen that may enter from the outside. In an embodiment, the encapsulation layer ENC may include a structure in which inorganic layers and organic layers are sequentially laminated.

The first transistor region TR1 described in FIG. 2 may correspond to the first transistor of FIG. 1, and the second transistor region TR2 described in FIG. 2 may correspond to at least one of the second, third, and fourth transistors of FIG. 1. Additionally, the third transistor region TR3 described in FIG. 2 may correspond to at least one of the fifth transistor and the sixth transistor of FIG. 1.

Below, the display device in another embodiment will be described with reference to FIG. 3. FIG. 3 is a cross-sectional view of an embodiment of the display device. Descriptions of components that are identical to the components described above will be omitted.

Referring to FIG. 3, a third gate insulating layer GI3 in an embodiment may be formed on the entirety of the surface of the substrate SUB. The third gate insulating layer GI3 may cover most of the surface of the substrate SUB. The third gate insulating layer GI3 may not expose a part of the first oxide semiconductor layer ACT1. The opening in the third gate insulating layer GI3 may be filled with the first data conductive layer. The first oxide semiconductor layer ACT1 may contact the first data conductive layer or covered by the third gate insulating layer GI3. Unlike the embodiment of FIG. 2, the first oxide semiconductor layer ACT1 may be spaced apart from the second inter-insulating layer ILD2. The first oxide semiconductor layer ACT1 may not contact the second inter-insulating layer ILD2.

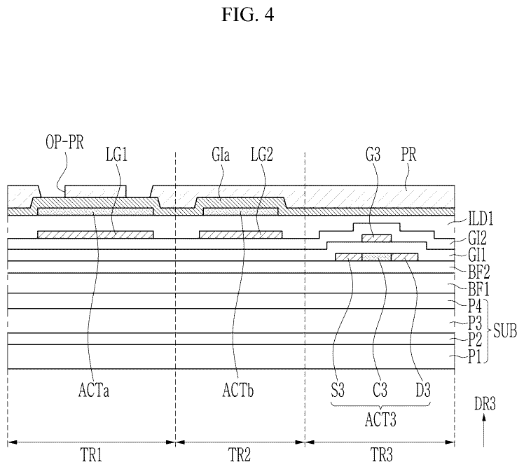

Hereinafter, a method for manufacturing the display device in an embodiment will be described with reference to FIGS. 4 to 9. FIGS. 4 to 9 are cross-sectional views according to a manufacturing method of the display device. Descriptions of components that are identical to the components described above will be omitted.

First, referring to FIG. 4, in an embodiment, a first oxide semiconductor material layer ACTa and a second oxide semiconductor material layer ACTb are formed on a first inter-insulating layer ILD1. The first oxide semiconductor material layer ACTa and the second oxide semiconductor material layer ACTb may be formed in the same process and may include the same oxide semiconductor material.

A third gate material layer GIa is formed on the first oxide semiconductor material layer ACTa and the second oxide semiconductor material layer ACTb. The third gate material layer GIa may be formed to overlap the entirety of the surface of the substrate SUB.

A photosensitive pattern PR is then formed on the third gate material layer GIa. The photosensitive pattern PR may define an opening OP-PR overlapping at least a portion of the first oxide semiconductor material layer ACTa.

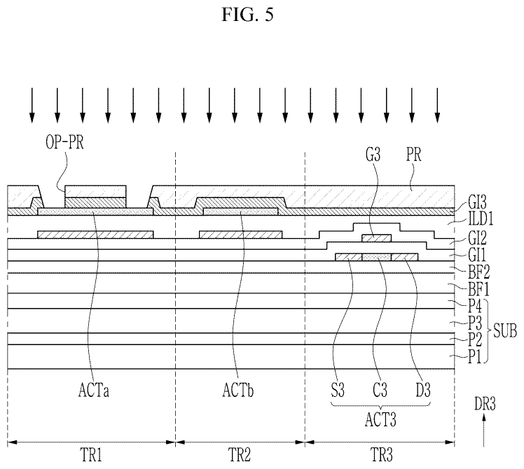

An etching process for the third gate material layer GIa is performed using the following photosensitive pattern PR as a mask. According to the etching process, a third gate insulating layer GI3 may be formed as shown in FIG. 5. The third gate insulating layer GI3 may define an opening OP3 overlapping a portion of the first oxide semiconductor material layer ACTa. The opening OP3 may expose at least a portion of the first oxide semiconductor material layer ACTa.

The first ion implantation process is performed on the next photosensitive pattern PR. The first ion implantation process may implant n+ ions—for example, boron ions. At this time, the injection process conditions may be injected at approximately 40 kiloelectron volts (keV) with an intensity of 5×10¹⁴ ions/cm².

According to the first ion implantation process, first doping may be performed on the first oxide semiconductor material layer ACTa in an area overlapping the opening OP-PR of the photosensitive pattern PR. The photosensitive pattern PR completely overlaps the second oxide semiconductor material layer ACTb. Therefore, no separate ions are implanted into the second oxide semiconductor material layer ACTb during the first ion implantation process.

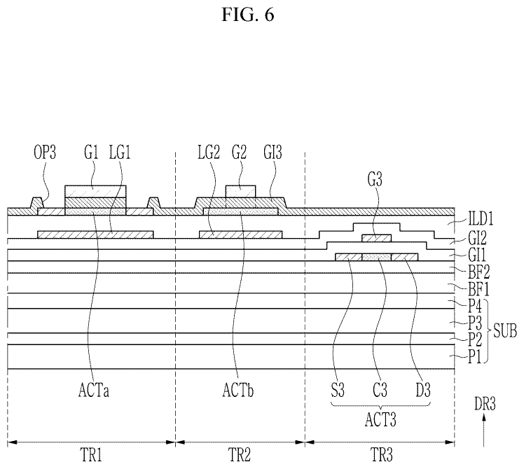

After the first ion implantation process, the photosensitive pattern PR is removed. Then, as shown in FIG. 6, the third gate conductive layer is formed on the third gate insulating layer GI3. The third gate conductive layer may include the first gate electrode G1 overlapping the first oxide semiconductor material layer ACTa, and the second gate electrode G2 overlapping the second oxide semiconductor material layer ACTb.

Then, the second ion implantation process is performed on the entirety of the surface of the substrate SUB. The second ion implantation process may be formed through the same process conditions as the first ion implantation process, or may be performed through different process conditions. The first gate electrode G1 and the second gate electrode G2 may serve as masks in the second ion implantation process.

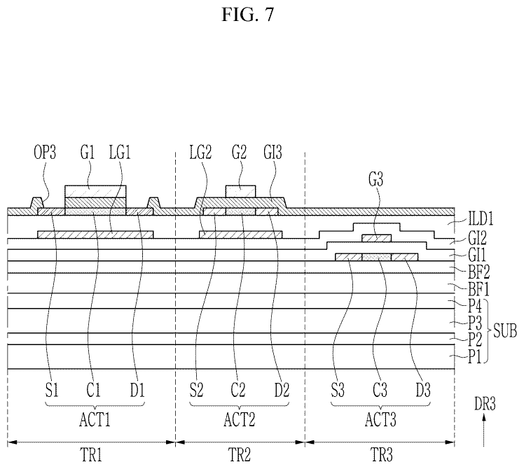

As illustrated in FIG. 7, a first channel region C1 overlapping the first gate electrode G1 may be formed through a second ion implantation process. A second channel region C2 overlapping the second gate electrode G2 may be formed through the second ion implantation process.

Additionally, the first-first region S1 and the first-second region D1 may be formed on opposite sides of the first channel region C1. The first-first region S1 and the first-second region D1 may be formed through two ion implantation processes. The second-first region S2 and the second-second region D2 may be formed on opposite sides of the second channel region C2. The second-first region S2 and the second-second region D2 may be formed through a single ion implantation process.

The first-first region S1 and the first-second region D1 may be regions doped with n+ ions. The first-first region S1 and the first-second region D1 may be doped with a first concentration; for example, the first concentration may be about 6×10¹⁴ ions/cm² to about 8×10¹⁴ ions/cm².

The second-first region S2 and the second-second region D2 may be regions doped with n+ ions. The second-first region S2 and the second-second region D2 may be doped with a second concentration; for example, the first concentration may be about 1×10¹⁴ ions/cm² to about 3×10¹⁴ ions/cm².

The first concentration doping the first-first region S1 and the first-second region D1 may be greater than the second concentration doping the second-first region S2 and the second-second region D2. In an embodiment, the first concentration may be more than twice the second concentration, for example.

Then, the second inter-insulating layer ILD2, the first data conductive layer, the first via layer VIA1, the second via layer VIA2, the first electrode E1, the barrier rib (also referred to as a pixel defining layer) PDL, the light-emitting layer EML, the second electrode E2, and the encapsulation layer ENC are sequentially formed on the second gate conductive layer, thereby manufacturing the display device illustrated in FIG. 2.

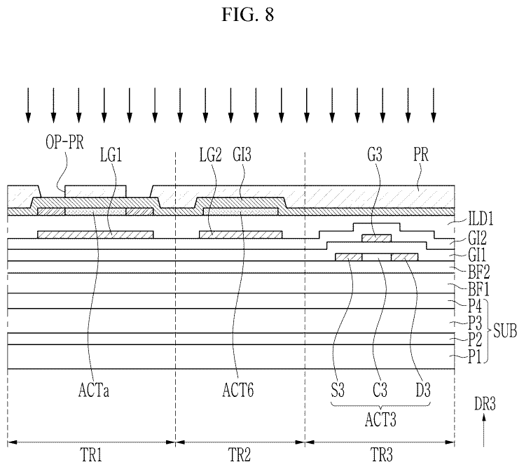

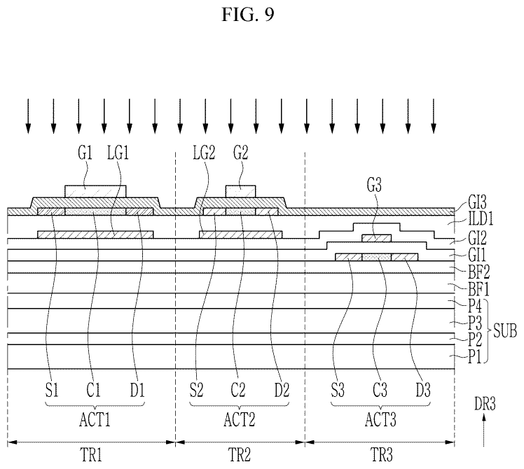

Referring to the following FIGS. 8 and 9, a method for manufacturing the display device in another embodiment will be described. Descriptions of components identical to those described above may be omitted.

First, referring to FIG. 8, in an embodiment, a first oxide semiconductor material layer ACTa and a second oxide semiconductor material layer ACTb are formed on the first inter-insulating layer ILD1. The first oxide semiconductor material layer ACTa and the second oxide semiconductor material layer ACTb may be formed in the same process and may include the same oxide semiconductor material.

The third gate insulating layer GI3 is formed on the first oxide semiconductor material layer ACTa and the second oxide semiconductor material layer ACTb. The third gate insulating layer GI3 may be formed to overlap the entirety of the surface of the substrate SUB.

The photosensitive pattern PR is formed on the third gate insulating layer GI3. The photosensitive pattern PR may define the opening OP-PR overlapping at least a portion of the first oxide semiconductor material layer ACTa.

The first ion implantation process is performed on the next photosensitive pattern PR. The first ion implantation process may implant n+ ions—for example, boron ions. At this time, the injection process conditions may be at about 40 keV with an intensity of 5×10¹⁴ ions/cm².

According to the first ion implantation process, first doping may be performed on the first oxide semiconductor material layer ACTa in an area overlapping the opening OP-PR of the photosensitive pattern PR. The photosensitive pattern PR completely overlaps the second oxide semiconductor material layer ACTb. Therefore, no separate ions are implanted into the second oxide semiconductor material layer ACTb during the first ion implantation process.

After the first ion implantation process, the photosensitive pattern PR is removed. Then, as shown in FIG. 9, the third gate conductive layer is formed on the third gate insulating layer GI3. The third gate conductive layer may include the first gate electrode G1 overlapping the first oxide semiconductor material layer ACTa, and the second gate electrode G2 overlapping the second oxide semiconductor material layer ACTb.

Then, the second ion implantation process is performed on the entirety of the surface of the substrate SUB. The second ion implantation process may be formed through the same process conditions as the first ion implantation process, or may be performed through different process conditions.

The first gate electrode G1 and the second gate electrode G2 may serve as masks in the second ion implantation process. The first channel region C1 overlapping the first gate electrode G1 may be formed through the second ion implantation process. The second channel region C2 overlapping the second gate electrode G2 may be formed through the second ion implantation process.

Additionally, the first-first region S1 and the first-second region D1 may be formed on opposite sides of the first channel region C1. The first-first region S1 and the first-second region D1 may be formed through two ion implantation processes. The second-first region S2 and the second-second region D2 may be formed on opposite sides of the second channel region C2. The second-first region S2 and the second-second region D2 may be formed through a single ion implantation process.

The first-first region S1 and the first-second region D1 may be regions doped with n+ ions. The first-first region S1 and the first-second region D1 may be doped with a first concentration; for example, the first concentration may be about 6×10¹⁴ ions/cm² to about 8×10¹⁴ ions/cm².

The second-first region S2 and the second-second region D2 may be regions doped with n+ ions. The second-first region S2 and the second-second region D2 may be doped with a second concentration; for example, the first concentration may be about 1×10¹⁴ ions/cm² to about 3×10¹⁴ ions/cm².

The first concentration doping the first-first region S1 and the first-second region D1 may be greater than the second concentration doping the second-first region S2 and the second-second region D2. In an embodiment, the first concentration may be more than twice the second concentration, for example.

Then, the second inter-insulating layer ILD2, the first data conductive layer, the first via layer VIA1, the second via layer VIA2, the first electrode E1, the pixel defining layer PDL, the light-emitting layer EML, the second electrode E2, and the encapsulation layer ENC are sequentially formed on the second gate conductive layer, thereby manufacturing the display device illustrated in FIG. 3.

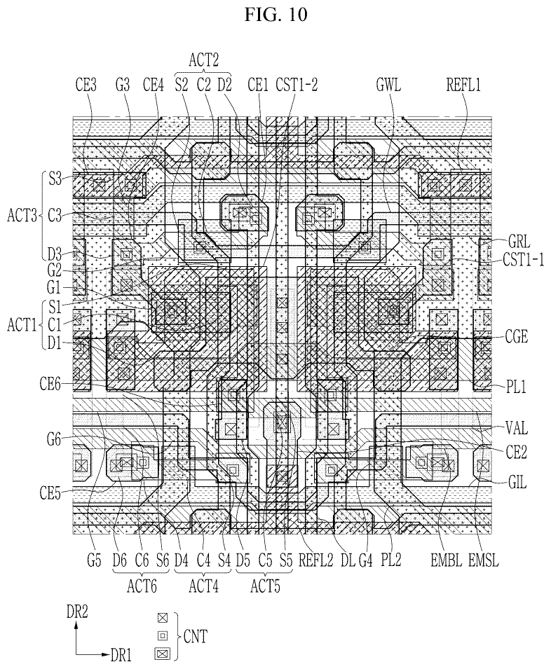

Hereinafter, one pixel of the display device in an embodiment will be examined with reference to FIGS. 10 to 17 above. FIGS. 10 to 17 are plan views showing each component according to one pixel. Descriptions of components that are identical to the components described above will be omitted. FIGS. 10 to 17 are plan views showing two pixels next (adjacent) to each other, and the two next pixels next (adjacent) to each other may have a symmetrical shape.

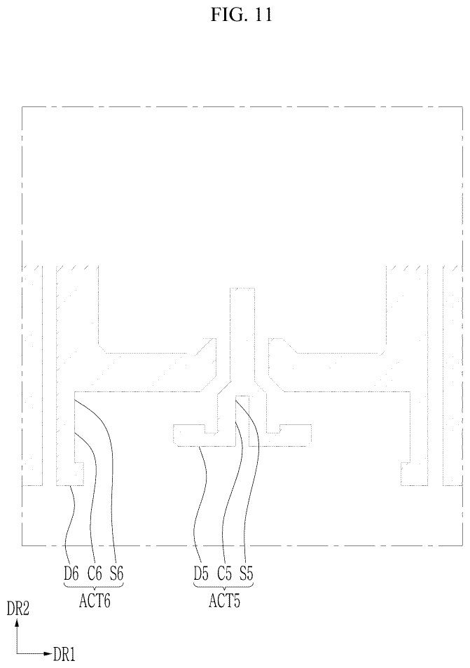

Referring to FIGS. 1, 2, 10 and 11, the display device in an embodiment includes a polycrystalline semiconductor layer disposed on a substrate. The polycrystalline semiconductor layer may have a planar shape as in FIG. 11. The polycrystalline semiconductor layer may include a fifth semiconductor layer ACT5 and a sixth semiconductor layer ACT6.

The fifth semiconductor layer ACT5 may include a fifth-first region S5, a fifth-second region D5, and a fifth channel region C5. The sixth semiconductor layer ACT6 may include a sixth-first region S6, a sixth-second region D6, and a sixth channel region C6. The fifth-first region (S5), the fifth-second region (D5), the sixth-first region (S6), and the sixth-second region (D6) are regions doped with impurities and may function as electrodes.

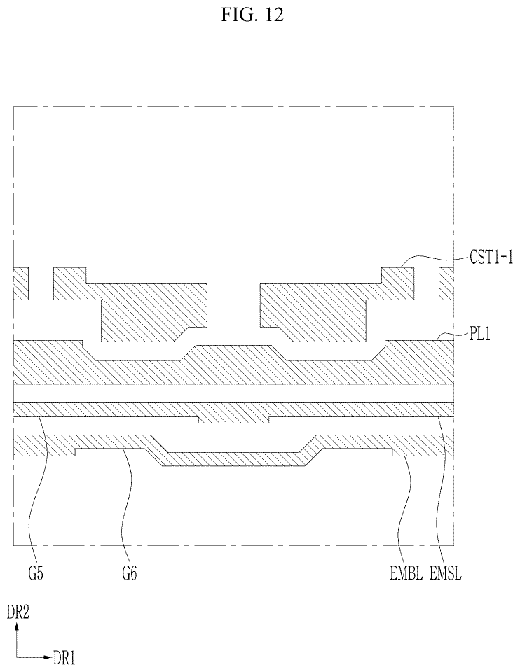

Referring to the following FIGS. 1, 2, 10, and 12, a first gate conductive layer may be disposed on a polycrystalline semiconductor layer. The first gate conductive layer may have a planar shape as shown in FIG. 12.

The first gate conductive layer may include a first light-emitting control line EMSL that applies a first light-emitting control signal to the fifth gate electrode G5 of the fifth transistor. Additionally, the first gate conductive layer may include a second light-emitting control line EMBL that applies a second light-emitting control signal to the sixth gate electrode G6 of the sixth transistor. Additionally, the first gate conductive layer may include a first power line PL1 that applies a first power voltage ELVDD. Additionally, the first gate conductive layer may include a first-first capacitor electrode CST1-1 forming a first capacitor.

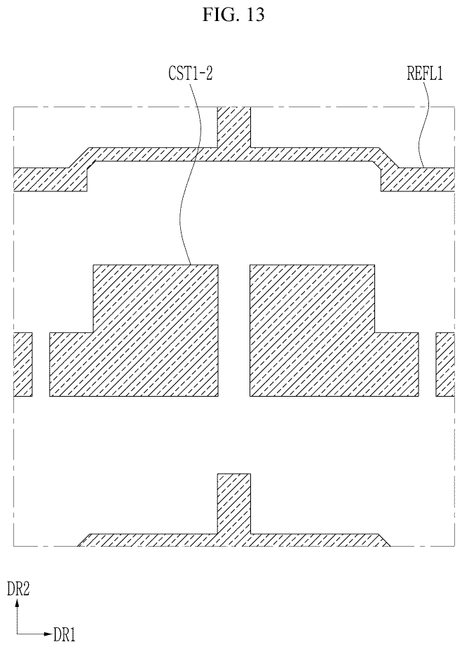

Referring to the following FIGS. 1, 2, 10, and 13, the second gate conductive layer may be disposed on the first gate conductive layer and the second gate insulating layer. The second gate conductive layer may have a planar shape as in FIG. 13.

The second gate conductive layer may include a first-second capacitor electrode CST1-2 forming the first capacitor. The first capacitor electrode CST1-1 and the first capacitor electrode CST1-2 may form a first capacitor as described in FIG. 1. Additionally, the second gate conductive layer may include a first reference power line REFL1 that provides a reference power voltage to the third transistor.

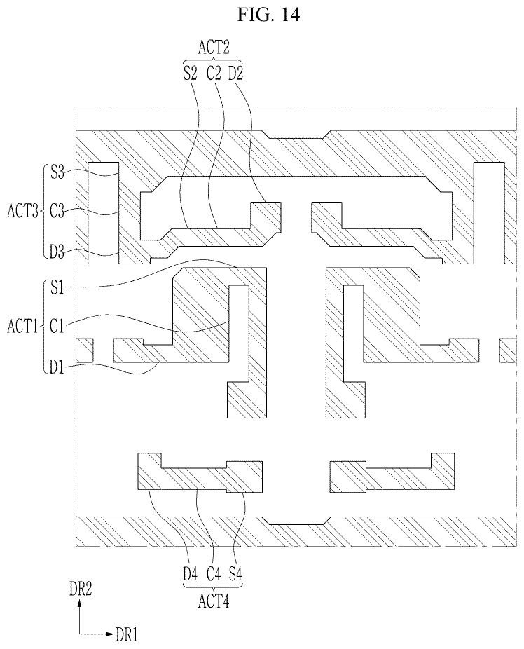

Referring to the following FIGS. 1, 2, 10, and 14, the oxide semiconductor layer may be disposed on the first inter-insulating layer ILD1. The oxide semiconductor layer may have a planar shape as illustrated in FIG. 14. The oxide semiconductor layer may include the first oxide semiconductor layer ACT1, the second oxide semiconductor layer ACT2, the third semiconductor layer (also referred to as a third oxide semiconductor layer) ACT3, and a fourth oxide semiconductor layer ACT4.

The first oxide semiconductor layer ACT1 may include the first-first region S1, the first-second region D1, and the first channel region C1. The second oxide semiconductor layer ACT2 may include the second-first region S2, the second-second region D2, and the second channel region C2. The third oxide semiconductor layer ACT3 may include the third-first region S3, the third-second region D3, and the third channel region C3. The fourth oxide semiconductor layer ACT4 may include a fourth-first region S4, a fourth-second region D4, and a fourth channel region C4.

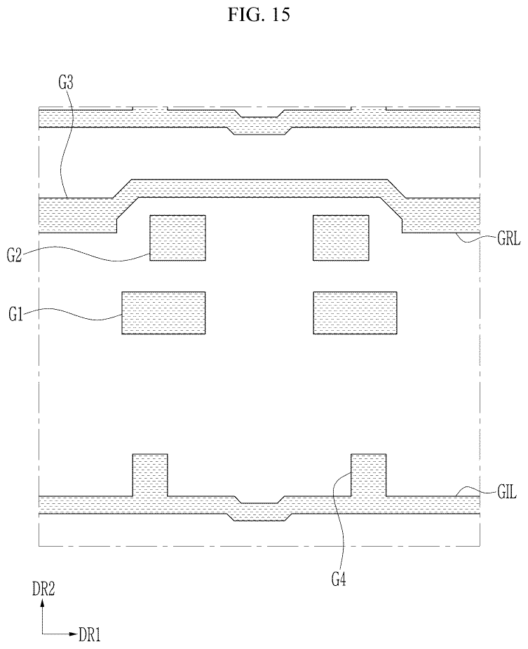

Referring to the following FIGS. 1, 2, 10, and 15, the third gate insulating layer may be disposed on the oxide semiconductor layer. The third gate conductive layer may be disposed on the third gate insulating layer. The third gate conductive layer may have a planar shape as illustrated in FIG. 15.

The third gate conductive layer may include the first gate electrode G1 included in the first transistor and the second gate electrode G2 included in the second transistor. Additionally, the third gate conductive layer may include a second scan line GRL including the third gate electrode G3 of the third transistor. The second scan line GRL may apply a second scan signal. Additionally, the third gate conductive layer may include a fourth gate electrode G4 of the fourth transistor and the third scan line GIL that applies a third scan signal to the fourth gate electrode G4.

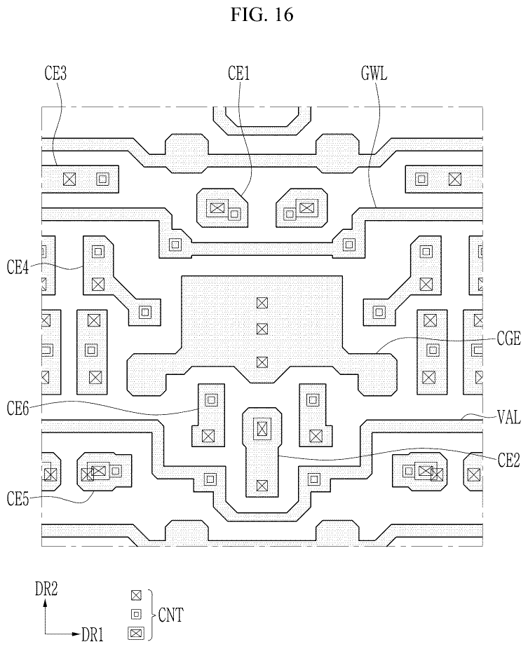

The second inter-insulating layer ILD2 may be disposed on the third gate conductive layer as illustrated in FIG. 2. The first data conductive layer may be disposed on the second inter-insulating layer ILD2. The first data conductive layer in an embodiment may have a planar shape as illustrated in FIG. 16.

Referring to FIGS. 1, 2, 10, and 16, the first data conductive layer may include a first scan line GWL that transmits a first scan signal to the second gate electrode of the second transistor. The first scan line GWL may be connected to the second transistor through a contact hole CNT. Additionally, the first data conductive layer may include a second initialization power line VAL that applies a second initialization voltage. The second initialization power line VAL may be electrically connected to the fourth transistor through the contact hole CNT.

Additionally, the first data conductive layer may include a plurality of connection electrodes. The first connection electrode CE1 may connect the data line and the second semiconductor layer, which will be described later. The second connection electrode CE2 may connect the third semiconductor layer and the reference power line. The third connection electrode CE3 may connect the reference power line and the third semiconductor layer. The fourth connection electrode CE4 may connect the first capacitor and the third semiconductor layer. The fifth connection electrode CE5 may connect the fourth semiconductor layer and the fifth semiconductor layer. Additionally, the fifth connection electrode CE5 may be electrically connected to the light-emitting element. The sixth connection electrode CE6 may connect the first semiconductor layer and the fifth semiconductor layer.

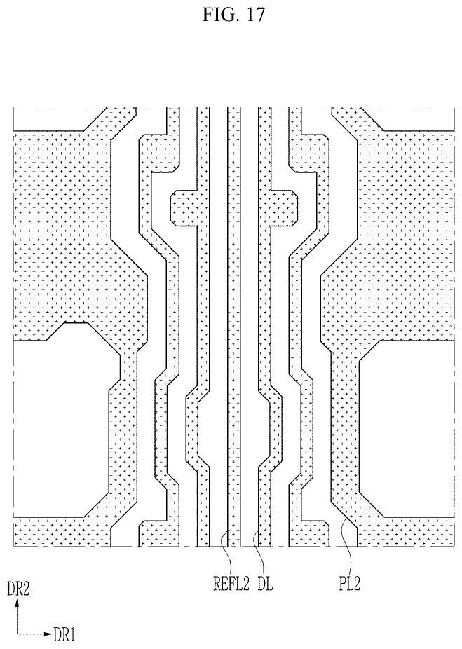

The second data conductive layer may be disposed above the first data conductive layer and the first via layer, as illustrated in FIG. 17. The second data conductive layer may have a planar shape as illustrated in FIG. 17.

Referring to FIGS. 1, 2, 10, and 17, the second data conductive layer may include a data line DL that transmits a data voltage to the second transistor. Additionally, the second data conductive layer may include a second power line PL2 that applies the first power voltage ELVDD. Additionally, the second data conductive layer may include a second reference power line REFL2 that transmits a reference power voltage and extends in the second direction DR2.

In the pixels described above, the first oxide semiconductor layer ACT1 may be applied to the first oxide semiconductor layer of FIG. 2, and the second oxide semiconductor layer ACT2, the third oxide semiconductor layer ACT3, and the fourth oxide semiconductor layer ACT4 may be applied to the second oxide semiconductor layer of FIG. 2. Additionally, the fifth oxide semiconductor layer ACT5 and the sixth oxide semiconductor layer ACT6 may be applied to the third oxide semiconductor layer of FIG. 2.

The doping region included in the first oxide semiconductor layer has a relatively high doping concentration, so the carrier is sufficient to ensure the reliability of the transistor. Additionally, the size of the first transistor may be reduced to provide the high-resolution display device.

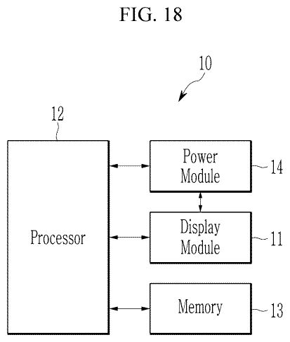

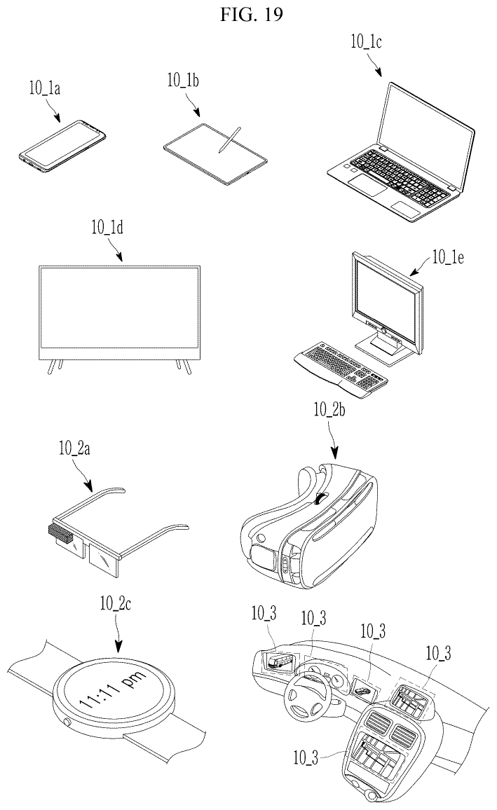

FIG. 18 is a block diagram of an electronic device according to an embodiment. FIG. 19 shows schematic diagrams of electronic devices according to various embodiments. A display device according to an embodiment may be applied to various electronic devices. An electronic device according to an embodiment may include the display device, and may further include modules or devices having additional functions other than the display device.

FIG. 18 is a block diagram of an electronic device according to an embodiment. Referring to FIG. 18, the electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for operations of the processor 12 or the display module 11. When the processor 12 executes an application stored in the memory 15, video data signals and/or input control signals are transmitted to the display module 11, and the display module 11 can process the received signals to output video information through the display screen.

The power module 14 may include a power supply module such as a power adapter or battery device, and a power conversion module that converts the power supplied by the power supply module to generate the power necessary for the operation of the electronic device 10.

At least one of components of the electronic device 11 may be included within the display device according to the above-described embodiments. Additionally, some of the individual modules that are functionally included within a single module may be incorporated into the display device, while others may be provided separately from the display device. For example, the display device may include the display module 11, while the processor 12, memory 13, and power module 14 may be provided in a form of other devices within the electronic device 11 that are not part of the display device.

FIG. 19 shows schematic diagrams of electronic devices according to various embodiments.

Referring to FIG. 19, various electronic devices with the display device according to the embodiments may include not only image display electronic devices such as smartphones 10_1a, tablet PCs 10_1b, laptops 10_1c, TVs 10_1d, desktop monitors 10_1e, but also wearable electronic devices with display modules such as smart glasses 10_2a, head-mounted displays 10_2b, smart watches 10_2c, as well as automotive electronic devices with display modules 10_3 such as those placed on car dashboards, center fascias, CID (Center Information Display), room mirror displays, and so on.

Although the embodiments of the disclosure have been described in detail above, the scope of the disclosure is not limited thereto, and various modifications and improvements made by those skilled in the art using the basic concepts of the disclosure defined in the following claims also fall within the scope of the disclosure.

What is claimed is:

1. An electronic device comprising:
a display device comprising:
a substrate:
a first transistor disposed on the substrate, the first transistor comprising:
a first oxide semiconductor layer including:
a first-first region;
a first-second region; and
a first channel region disposed between the first-first region and the first-second region; and
a first gate electrode overlapping a portion of the first oxide semiconductor layer,
a second transistor disposed on the substrate, the second transistor comprising:
a second oxide semiconductor layer including:
a second-first region;
a second-second region; and
a second channel region disposed between the second-first region and the second-second region; and
a second gate electrode that overlaps a portion of the second oxide semiconductor layer; and
a light-emitting element electrically connected to the first transistor,
wherein,
the first-first region and the first-second region are regions doped with a first concentration,
the second-first region and the second-second region are regions doped with a second concentration, and
the first concentration is greater than the second concentration.

2. The electronic device of claim 1, wherein:
the first concentration is about 6×10¹⁴ ions per square centimeter to about 8×10¹⁴ ions per square centimeter.

3. The electronic device of claim 2, wherein:
the second concentration is from about 1×10¹⁴ ions per square centimeter to about 3×10¹⁴ ions per square centimeter.

4. The electronic device of claim 1, wherein:
the first concentration is at least twice the second concentration.

5. The electronic device of claim 1, wherein:
the first oxide semiconductor layer and the second oxide semiconductor layer are disposed at the same level.

6. The electronic device of claim 1, further comprising:
a third transistor including a polycrystalline semiconductor layer.

7. The electronic device of claim 1, wherein:
at least one of the first channel region and the second channel region has a channel length of about 3.0 micrometers or less.

8. The electronic device of claim 1, further comprising:
a gate insulating layer disposed on the first oxide semiconductor layer and the second oxide semiconductor layer.

9. The electronic device of claim 8, wherein:
the gate insulating layer defines an opening overlapping the first-first region and the first-second region.

10. The electronic device of claim 9, further comprising:
an inter-insulating layer disposed over the gate insulating layer.

11. The electronic device of claim 10, wherein:
the inter-insulating layer fills at least a portion of the opening.

12. The electronic device of claim 1, wherein:
the first gate electrode is disposed over the first channel region, and
the second gate electrode is disposed over the second channel region.

13. A method for manufacturing a display device, the method comprising:
forming a first oxide semiconductor material layer and a second oxide semiconductor material layer on a substrate;
forming a gate insulating layer on the first oxide semiconductor material layer and the second oxide semiconductor material layer;
forming a photosensitive pattern defining a first opening on the gate insulating layer;
performing a first ion implantation process on the photosensitive pattern;
removing the photosensitive pattern;
forming a first gate electrode and a second gate electrode on the gate insulating layer, and
performing a second ion implantation process on the first gate electrode and the second gate electrode.

14. The method for manufacturing the display device of claim 13, wherein:
the first oxide semiconductor material layer is formed as a first oxide semiconductor layer including a first-first region, a first-second region, and a first channel region disposed between the first-first region and the first-second region,
the second oxide semiconductor material layer is formed as a second oxide semiconductor layer including a second-first region, a second-second region, and a second channel region disposed between the second-first region and the second-second region,
the first-first region and the first-second region are regions doped with the first concentration,
the second-first region and the second-second region are regions doped with a second concentration, and
the first concentration is greater than the second concentration.

15. The method for manufacturing the display device of claim 14, wherein:
in the first ion implantation process,
the first oxide semiconductor material layer is at least partially doped in a region overlapping the first opening.

16. The method for manufacturing the display device of claim 14, wherein:
in the second ion implantation process,
the first oxide semiconductor material layer is doped in a region that does not overlap the first gate electrode, and
the second oxide semiconductor material layer is doped in a region that does not overlap the second gate electrode.

17. The method for manufacturing the display device of claim 14, wherein:
the gate insulating layer defines a second opening overlapping a portion of the first oxide semiconductor material layer.

18. The method for manufacturing the display device of claim 17, wherein:
the second opening overlaps the first-first region and the first-second region.

19. The method for manufacturing the display device of claim 17, further comprising:
forming an inter-insulating layer on the first gate electrode and the second gate electrode, and
the inter-insulating layer fills at least a portion of the second opening.

20. The method for manufacturing the display device of claim 13, further comprising:
forming a third transistor including a polycrystalline semiconductor layer.
